(19) United States
(12) Patent Application Publication
(10) Pub. No.: US 2020/0091355 A1
(43) Pub. Date: Mar. 19, 2020

(54) METHOD AND SYSTEM FOR MULTILAYER TRANSPARENT ELECTRODE FOR TRANSPARENT PHOTOVOLTAIC DEVICES

(71) Applicant: Ubiquitous Energy, Inc., Redwood City, CA (US)

(72) Inventors: Miles C. Barr, Redwood City, CA (US); Richa Pandey, Sunnyvale, CA (US); Matthew E. Sykes, San Mateo, CA (US); John A. Love, Mountain View, CA (US); Gabriel A. Flores, Burlingame, CA (US)

(73) Assignee: Ubiquitous Energy, Inc., Redwood City, CA (US)

(21) Appl. No.: 16/570,897

(22) Filed: Sep. 13, 2019

Related U.S. Application Data
(60) Provisional application No. 62/731,600, filed on Sep. 14, 2018.

(51) Int. Cl. H01L 31/0224; H01L 31/18; H01L 31/0216; H01L 31/0236

(52) U.S. Cl. CPC H01L 31/022425; H01L 31/02366; H01L 31/02168; H01L 31/1884

(57) ABSTRACT

A transparent photovoltaic device includes a transparent substrate and a transparent bottom electrode coupled to the transparent substrate. The transparent photovoltaic device also includes an active layer coupled to the transparent bottom electrode and a transparent multilayer top electrode that includes a seed layer coupled to the active layer and a metal layer coupled to the seed layer. The transparent photovoltaic device is characterized by an average visible transmission (AVT) greater than 25% and a top electrode sheet resistance that is less than 100 Ohm/sq.

### CROSS-REFERENCES TO RELATED APPLICATIONS

This application claims priority to U.S. Provisional Patent Application No. 62/731,600, filed on Sep. 14, 2018, entitled “Method and System for Multilayer Transparent Electrode for Transparent Photovoltaic Devices,” the disclosure of which is hereby incorporated by reference in its entireties for all purposes.

### BACKGROUND OF THE INVENTION

There has been a growing interest in transparent photovoltaic devices that can be integrated into architectural glass in homes and skyscrapers, automotive glass, as well as display screens used in a desktop monitor, laptop or notebook computer, tablet computer, mobile phone, e-readers and the like. Transparent photovoltaic devices may include active materials that transmit visible wavelengths and may selectively absorb light in the ultraviolet (UV) and near infrared (NIR) wavelengths. For architectural glass applications, there is a need for improved transparent photovoltaic devices that exhibit high ratios of average visible transmission (AVT) over fraction of solar transmission (Tsol), high selectivity (defined as the ratio of AVT over solar heat gain coefficient (SHGC)), and low emissivity values.

### SUMMARY OF THE INVENTION

According to some embodiments of the present invention, a multilayer top electrode, which may include one or more discrete metal layers, is utilized in transparent photovoltaic devices to improve NIR reflection in the device, which reduces the Tsol, SHGC, and the device emissivity.

According to an embodiment of the present invention, a transparent photovoltaic device is provided. The transparent photovoltaic device includes a transparent substrate and a transparent bottom electrode coupled to the transparent substrate. The transparent photovoltaic device also includes an active layer coupled to the transparent bottom electrode and a transparent multilayer top electrode that includes a seed layer coupled to the active layer and a metal layer coupled to the seed layer. The transparent photovoltaic device is characterized by an average visible transmission (AVT) greater than 25%, and a top electrode sheet resistance that is less than 100 Ohm/sq. In a particular embodiment, the ratio of AVT to fraction of transmitted solar radiation (AVT/Tsol) is greater than 1.3 and less than or equal to 2.5.

According to another embodiment of the present invention, a transparent photovoltaic device is provided. The transparent photovoltaic device includes a transparent substrate and a transparent bottom electrode coupled to the transparent substrate. The transparent photovoltaic device also includes an active layer coupled to the transparent bottom electrode and a transparent multilayer top electrode. The transparent multilayer top electrode includes a seed layer deposited on the active layer, a first metal layer deposited on the seed layer, an interconnect layer deposited on the first metal layer, and a second metal layer deposited on the interconnect layer. The transparent photovoltaic device is characterized by an average visible transmission (AVT) greater than 25%, and a top electrode sheet resistance that is less than 100 Ohm/sq. In a specific embodiment, the ratio of the AVT to fraction of transmitted solar radiation (AVT/Tsol) is greater than 1.7 and less than or equal to 2.5.

According to a particular embodiment of the present invention, an insulated glass unit (IGU) including a transparent photovoltaic device is provided. The IGU includes a first glazing and a second glazing opposing the first glazing. The transparent photovoltaic device is disposed between the first glazing and the second glazing and includes a transparent substrate, a transparent bottom electrode coupled to the transparent substrate, an active layer coupled to the transparent bottom electrode, and a transparent multilayer top electrode. The transparent multilayer top electrode includes a charge selective seed layer coupled to the active layer and a metal layer coupled to the charge selective seed layer. The insulated glass unit is characterized by an average visible transmission (AVT) greater than 25%. In some embodiments, the IGU is characterized by a selectivity greater than 1.3 and less than or equal to 2.5, although this is not required by the present invention

According to some embodiments, a photovoltaic device includes a transparent substrate, a transparent bottom electrode coupled to the transparent substrate, an active layer, which can include a tandem or multi junction cell, coupled to the transparent bottom electrode, and a transparent top electrode. The transparent bottom electrode can include a first transparent conducting oxide layer, a second metal layer, and a second transparent conducting oxide layer. The active layer is transparent in the visible wavelength range in some embodiments and the active layer can include an organic small molecule semiconductor with selective absorption in the NIR.

The transparent top electrode includes a seed layer, which can be a charge selective seed layer, coupled to the active layer, and a metal layer coupled to the seed layer. The seed layer can include one of HAT-CN, TPBi:C60, indium tin oxide (ITO), ZnO, SnO₂, antimony doped tin oxide (ATO), aluminum-doped zinc-oxide (AZO), indium-doped cadmium-oxide, fluorine doped tin oxide (FTO), or a combination thereof and can have a seed layer thickness ranging from 0.1 nm to 100 nm. The metal layer can include at least one of Ag, Au, Al, Sn, or Cu. In some embodiments, the metal layer includes an alloy of Ag, Au, Sn, Al, Cu, or combinations thereof, for example, Al doped Ag or Sn doped Ag. The metal layer can have a thickness ranging from 3 nm to 30 nm. The transparent top electrode can also include an anti-reflection layer coupled to the metal layer.

The photovoltaic device is characterized by an AVT value that is greater than 25%, and a top electrode sheet resistance that is less than 100 Ohm/sq. The AVT can be greater 35%, greater than 45%, or greater than 60%.

According to some other embodiments, a transparent photovoltaic device includes a transparent substrate, a transparent bottom electrode coupled to the transparent substrate, an active layer coupled to the transparent bottom electrode, and a transparent top electrode. The transparent top electrode includes a seed layer coupled to the active layer, a first metal layer coupled to the seed layer, an interconnect layer (e.g., a transparent conducting oxide) coupled to the first metal layer, and a second metal layer coupled to the interconnect layer. The photovoltaic device is characterized by an AVT that is greater than 25%, and a top electrode sheet resistance that is less than 100 Ohm/sq.

The active layer can include a transparent organic or inorganic material. The interconnect layer can have a thickness ranging from 5 nm to 120 nm. Each of the first metal layer and the second metal layer can have a thickness ranging from 3 nm to 30 nm. The seed layer can be charge selective. As an example, the seed layer can include one of HAT-CN, TPBi:C60, indium tin oxide (ITO), ZnO, SnO₂, antimony doped tin oxide (ATO), aluminum-doped zinc-oxide (AZO), indium-doped cadmium-oxide, fluorine doped tin oxide (FTO), or a combination thereof. The top electrode can also include an anti-reflection layer coupled to the second metal layer. The transparent bottom electrode can include a transparent conducting oxide. In other embodiments, the transparent bottom electrode includes a first transparent seed layer (e.g., a transparent conducting oxide or a transparent oxide), a third metal layer, and a charge selective layer (e.g., a transparent conducting oxide or a transparent oxide).

According to some further embodiments, a photovoltaic device includes a transparent substrate, a transparent bottom electrode coupled to the transparent substrate, active layer(s) comprising a single junction or multiple junctions connected through charge recombination zones coupled to the transparent bottom electrode, and a multilayer top electrode. The multilayer top electrode includes a charge selective seed layer coupled to the active layer(s), and a metal layer coupled to the charge selective seed layer. The photovoltaic device is characterized by an AVT that is greater than about 25%, and a top electrode sheet resistance that is less than about 100 ohm/sq.

The active region can include a single junction or multiple junctions connected through charge recombination zones. In one embodiment, the active region includes an organic small molecule semiconductor with selective absorption in the NIR. The transparent multilayer top electrode can include an interconnect layer coupled to the metal layer and a second metal layer coupled to the interconnect layer. The transparent multilayer top electrode can also include an anti-reflection layer coupled to the second metal layer. In an embodiment, the transparent multilayer top electrode includes one or more additional interconnect layers and one or more additional metal layers, each of the one or more additional interconnect layers being coupled to an adjacent metal layer of the one or more additional metal layers. Furthermore, the transparent multilayer top electrode can include an anti-reflection layer coupled to the top-most metal layer of the one or more additional metal layers.

The charge selective seed layer can include HAT-CN, TPBi:C60, indium tin oxide (ITO), ZnO, SnO₂, antimony doped tin oxide (ATO), aluminum-doped zinc-oxide (AZO), indium-doped cadmium-oxide, fluorine doped tin oxide (FTO), or a combination thereof. The charge selective seed layer can have a thickness ranging from 0.1 nm to 100 nm. The metal layer can include Ag, Au, Al, Sn or Cu. The metal layer can include an alloy of Ag, Au, Sn, Al, or Cu or combinations thereof, for example Al doped Ag an can have a thickness ranging from 3 nm to 30 nm. The interconnect layer, which can be a transparent conducting oxide or a transparent oxide, can have a thickness ranging from 5 nm to 120 nm. The transparent bottom electrode can include a transparent conducting oxide.

According to an alternative embodiment of the present invention, a photovoltaic device is provided. The photovoltaic device includes a transparent substrate, a transparent bottom electrode coupled to the transparent substrate, an active layer coupled to the transparent bottom electrode, and a transparent top electrode. The transparent top electrode includes a charge selective seed layer coupled to the active layer and a first metal layer coupled to the charge selective seed layer. The photovoltaic device is characterized by a peak in absorption at a wavelength above 650 nm or below 450 nm, an average visible transmission greater than 25%, and a selectivity greater than 1.3. In an embodiment, the photovoltaic device also includes an interconnect layer coupled to the first metal layer and a second metal layer coupled to the interconnect layer. The second metal layer is electrically coupled to the first metal layer through the interconnect layer. In an embodiment, the selectivity is greater than 1.4, for example, between 1.4 and 2.19, although this is not required by the present invention.

### BRIEF DESCRIPTION OF THE DRAWINGS

FIG. 1 shows a schematic cross-sectional view of a transparent photovoltaic device that includes a multilayer top electrode according to some embodiments of the present invention.

FIG. 2A shows a schematic cross-sectional view of a photovoltaic device that includes a multilayer top electrode with a single metal layer according to some embodiments of the present invention.

FIG. 2B shows a schematic cross-sectional view of a photovoltaic device that includes a multilayer bottom electrode with a single metal layer paired with a multilayer top electrode with a single metal layer according to some embodiments of the present invention.

FIG. 3A shows a schematic cross-sectional view of a photovoltaic device that includes a multilayer top electrode with two metal layers according to some embodiments of the present invention.

FIG. 3B shows a schematic cross-sectional view of a photovoltaic device that includes a multilayer bottom electrode with a single metal layer paired with a multilayer top electrode with two metal layers according to some embodiments of the present invention.

FIG. 4 shows a schematic energy level diagram whereby the charge selective seed layer functions as an electron transport layer within a transparent photovoltaic device according to some embodiments of the present invention.

FIG. 5 shows a schematic energy level diagram whereby the charge selective seed layer functions as a hole transport layer within a transparent photovoltaic device according to some embodiments of the present invention.

FIG. 6 shows experimental values for AVT vs. sheet resistance for various types of top electrode configurations according to some embodiments of the present invention.

FIG. 7A shows simulated transmission curves vs. wavelength for a commercial ITO electrode (solid line), a multilayer electrode with a single Ag layer (dashed line), and a multilayer electrode with two Ag layers (dotted line) according to some embodiments of the present invention.

FIG. 7B shows simulated reflection curves vs. wavelength for the commercial ITO electrode (solid line), the multilayer electrode with a single Ag layer (dashed line), and the multilayer electrode with two Ag layers (dotted line), according to some embodiments of the present invention.

FIG. 8 illustrates schematically a reflection curve vs. wavelength (solid line) of a multilayer top electrode, a representative absorption curve for a non-selective active layer absorber (dashed line), and the corresponding enhanced absorption curve (dotted line) when paired with the multilayer top electrode, according to some embodiments of the present invention.

FIG. 9 shows exemplary spectra of absorption coefficients for D100, C60, and a D100:C60 blend, respectively, according to some embodiments of the present invention.

FIG. 10A shows simulated transmission curves vs. wavelength of various electrode configurations for OPVs according to some embodiments of the present invention.

FIG. 10B shows simulated reflection curves vs. wavelength of various electrode configurations for the OPV devices according to some embodiments of the present invention.

FIG. 10C shows simulated active layer absorption curves vs. wavelength of various electrode configurations for the OPV devices according to some embodiments of the present invention.

FIG. 11A shows simulated transmission curves vs. wavelength for two electrode configurations used in inorganic photovoltaic devices that include CuIn_{0.69}Ga_{0.31}Se (CIGS) in the active layer according to some embodiments of the present invention.

FIG. 11B shows simulated reflection curves vs. wavelength for the two electrode configurations used in the inorganic photovoltaic devices that include CIGS in the active layer according to some embodiments of the present invention.

FIG. 11C shows simulated active layer absorption curves vs. wavelength for the two electrode configurations used in the inorganic photovoltaic devices that include CIGS in the active layer according to some embodiments of the present invention.

FIG. 12A shows simulated transmission curves vs. wavelength for the two electrode configurations used in photovoltaic devices that include methylammonium lead iodide (MAPbI₃) perovskite in the active layer according to some embodiments of the present invention.

FIG. 12B shows simulated reflection curves vs. wavelength for the two electrode configurations used in the photovoltaic devices that include MAPbI₃ perovskite in the active layer according to some embodiments of the present invention.

FIG. 12C shows simulated active layer absorption curves vs. wavelength for the two electrode configurations used in the photovoltaic devices that include MAPbI₃ perovskite in the active layer according to some embodiments of the present invention.

FIG. 13 is a table that summarizes the structures and properties of transparent photovoltaic devices with a variety of electrode and active layer combinations, as discussed in relation to FIGS. 10A-10C, 11A-11C, and 12A-12C, according to various embodiments of the present invention.

FIG. 14A shows experimental current density-voltage curves of OPVs with a variety of electrode and active layer combinations tested under a solar simulator calibrated to AM1.5G illumination according to some embodiments of the present invention.

FIG. 14B shows the corresponding external quantum efficiency (EQE) curves vs. wavelength for these OPVs according to some embodiments of the present invention.

FIG. 14C shows the corresponding transmission curves vs. wavelength of the various OPVs obtained from experiment according to some embodiments of the present invention.

FIG. 15A shows exemplary spectra of absorption coefficients for organic active layer materials, according to some embodiments of the present invention.

FIG. 15B shows an experimental current density-voltage curve of an OPV tested under a solar simulator calibrated to AM1.5G illumination according to some embodiments of the present invention.

FIG. 15C shows the corresponding EQE curve vs. wavelength for the OPV of FIG. 15B according to some embodiments of the present invention.

FIG. 15D shows the corresponding transmission curve vs. wavelength of the OPV of FIG. 15B obtained from experiment according to some embodiments of the present invention.

FIG. 16 is a table that summarizes the measured optical and electrical performance of a variety of electrode combinations as discussed in FIGS. 10A-C, 14A-C, and 19B-C according to some embodiments of the present invention.

FIG. 17 is a table that summarizes the measured optical and electrical performance of transparent OPVs comprising a variety of electrode combinations as discussed in FIGS. 10A-C, 14A-C, 15A-D, and 19B-C according to some embodiments of the present invention.

FIG. 18 is a table showing the experimental emissivity values of various organic photovoltaic devices (OPVs) with different electrode configurations according to various embodiments of the present invention.

FIG. 19A shows a schematic of an example insulated glass unit (IGU) construction that was used to calculate thermal properties of photovoltaic devices in the present invention.

FIG. 19B is a table that summarizes the structures and properties of transparent photovoltaic devices with a variety of electrode and active layer combinations, as discussed in relation to FIGS. 10A-10C, 11A-11C, 12A-12C, and 15A-D, when integrated into an insulated glass unit according to FIG. 19A, according to various embodiments of the present invention.

FIG. 19C is a table that summarizes the measured optical and electrical performance of transparent OPVs comprising a variety of electrode combinations as discussed in FIGS. 10, 13, 14A-C, and 15A-D, if they were to be integrated into an insulated glass unit as in FIG. 19A, according to some embodiments of the present invention.

### DETAILED DESCRIPTION OF SPECIFIC EMBODIMENTS

Average Visible Transmission (AVT) is defined as the weighted average of the transmission spectrum against the photopic response of the human eye.

$$AVT = \frac{\int T ( λ ) P ( λ ) S ( λ ) d ( λ )}{\int P ( λ ) S ( λ ) d ( λ )}$$

where λ is the wavelength, T is the transmission, P is the photopic response, and S is the solar photon flux (AM1.5G) for window applications, or 1 for other applications. AVT is also referred to as Tvis in the window industry. For the purpose of this invention, the word “transparent” means AVT greater than zero.

Tsol is the fraction of solar radiation admitted through a medium and can be referred to as the fraction of transmitted solar radiation. When a transparent photovoltaic device is used for architectural glass applications, it may be desired that the transparent photovoltaic device is selective in that it rejects as much of the solar spectrum as possible to achieve low values of Tsol while still allowing a significant fraction of visible light to be transmitted. This can be quantified as the ratio of AVT over Tsol (AVT/Tsol), in which larger values are generally desirable. By maintaining high AVT while rejecting as much non-visible light as possible, a transparent photovoltaic device can be engineered with a high (AVT/Tsol). A relatively high reflection in the NIR and IR wavelengths may decrease the Tsol.

According to some embodiments of the present invention, transparent photovoltaic devices may utilize a multilayer top electrode that includes one or more discrete metal layers to achieve high AVT, enhanced active layer absorption in the NIR and IR wavelengths (thus larger short circuit current density Jsc), high AVT/Tsol, low emissivity (low-e), as well as low sheet resistance of the electrode. In some embodiments, a multilayer bottom electrode that includes one or more discrete metal layers may also be utilized.

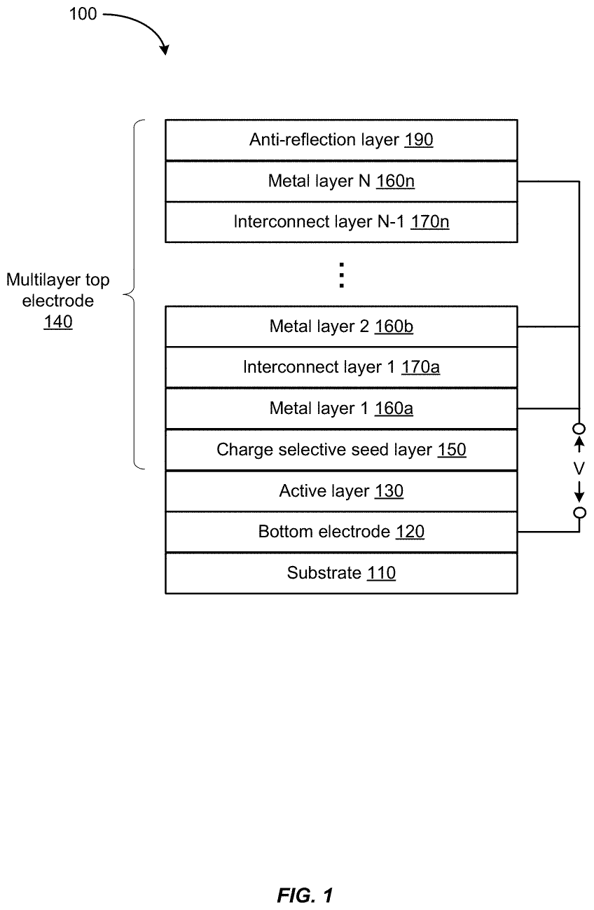

FIG. 1 shows a schematic cross-sectional view of a transparent photovoltaic device 100 according to some embodiments of the present invention. The transparent photovoltaic device 100 may include a transparent substrate 110, a transparent bottom electrode 120, an active layer 130, and a multilayer top electrode 140. The substrate 110 may include glass, quartz, or polymer materials.

The bottom electrode 120 may include transparent oxides, such as indium tin oxide (ITO), ZnO, SnO₂, antimony doped tin oxide (ATO), aluminum-doped zinc-oxide (AZO), indium-doped cadmium-oxide, fluorine doped tin oxide (FTO), indium zinc oxide (IZO), carbon nanotubes, graphene, silver nanowires, or combinations thereof. In some embodiments, the bottom electrode 120 may also include one or more discrete metal layers, similar to the multilayer top electrode 140.

The active layer 130 may include a single layer or multiple layers. The active layer may include organic semiconducting materials such as small molecules or polymers or other molecular excitonic materials. The active layer may also include inorganic materials, such as CuIn₁₋ₓGaₓSe (CIGS), amorphous Si, methylammonium lead iodide (MAPbI₃) perovskite, quantum dots, carbon nanotubes, and the like. Some common organic small molecules may include phthalocyanines, porphyrins, naphthalocynanines, squaraines, boron-dipyrromethenes, fullerenes, naphthalenes and perylenes. Some examples include chloroaluminum phthalocyanine (ClAlPc) or tin phthalocyanine (SnPc) as an electron donor, and fullerene (C60) acting as an electron acceptor. Additional descriptions of possible materials for the active layer are provided in U.S. Patent Application Publication Nos. 2012/0186623 and 2018/0108846, U.S. patent application Ser. Nos. 16/010,374, 16/010,364, 16/010,365, 16/010,371, and 16/010,369, and PCT Application Serial No. PCT/US2018/037923, the contents of which are incorporated by reference in their entirety for all purposes.

The multilayer top electrode 140 may include a charge selective seed layer 150, a metal layer 1 160a, and an anti-reflection layer 190. The anti-reflection layer 190 is optional. The multilayer top electrode 140 may further include one or more additional discrete metal layers 160a through 160n and one or more interconnect layers 170a through 170n, where each respective interconnect layer 170 is disposed between each pair of adjacent metal layers 160. Each of the charge selective seed layer 150, the metal layer 1 160a, the interconnect layer 1 170a, and the anti-reflection layer 190 may include a single layer or multiple layers. Thus, although metal layers 160 may be referred to using a common reference number, it should be appreciated that the metal materials present in each of metal layers 160 can be different metals. As an example, a first metal (or metal alloy) could be utilized for metal layer 1 160a and a different metal (or metal alloy) could be utilized for metal layer 2 160b. Similarly, although interconnect layers 170 may be referred to using a common reference number, it should be appreciated that the materials present in each of interconnect layers 170 can be different metals. One of ordinary skill in the art would recognize many variations, modifications, and alternatives.

The charge selective seed layer 150 may include oxides, organic materials, refractory metals, or combinations thereof. The charge selective seed layer 150 may serve as a charge carrier transport layer (e.g., electron transport layer or hole transport layer). The charge selective seed layer 150 may exhibit electrical conductivity and electronic properties that promote conformal growth of the overlying metal layer 1 160a. In various embodiments, the seed layer can have a thickness that ranges from 0.1 nm to 100 nm. For example, the thickness of the seed layer can be less than 1 nm, less than 5 nm, less than 10 nm, less than 20 nm, less than 30 nm, less than 40 nm, less than 50 nm, or less than 100 nm.

Each metal layer 160 may include a pure metal such as Ag, Au, Al, or Cu, or doped metals such as Al:Ag, or Ag layered with ultra-thin refractory metals such as Cr. The metal layer 1 160a may have the lowest resistance among the various layers and may provide the dominant path for lateral charge conduction in the multilayer top electrode 140. In various embodiments, the metal layer can have a thickness ranging from 3 nm to 30 nm, for example, from 3 nm to 10 nm, from 10 nm to 15 nm, from 15 nm to 20 nm, from 20 nm to 25 nm, or from 25 nm to 30 nm.

Each interconnect layer 170 may include oxides, organic materials, refractory metals, or combinations thereof. The interconnect layer 1 170a may function as an optical spacer while providing an electrical connection between two neighboring metal layers, so that the overall sheet resistance of the composite electrode 140 is reduced from that of a multilayer electrode with a single metal layer. In various embodiments, the interconnect layer can have a thickness ranging from 1 nm to 120 nm. For example, the thickness can be less than 5 nm, less than 10 nm, less than 20 nm, less than 30 nm, less than 40 nm, less than 50 nm, less than 60 nm, less than 70 nm, less than 80 nm, less than 90 nm, less than 100 nm, less than 110 nm, or less than 120 nm.

The anti-reflection layer 190 may be an optically engineered layer that reduces reflection at visible wavelengths while improving the AVT of the overall photovoltaic device 100. The anti-reflection layer 190 need not be electrically conducting and may include oxides, carbides, nitrides, sulfides or organic materials.

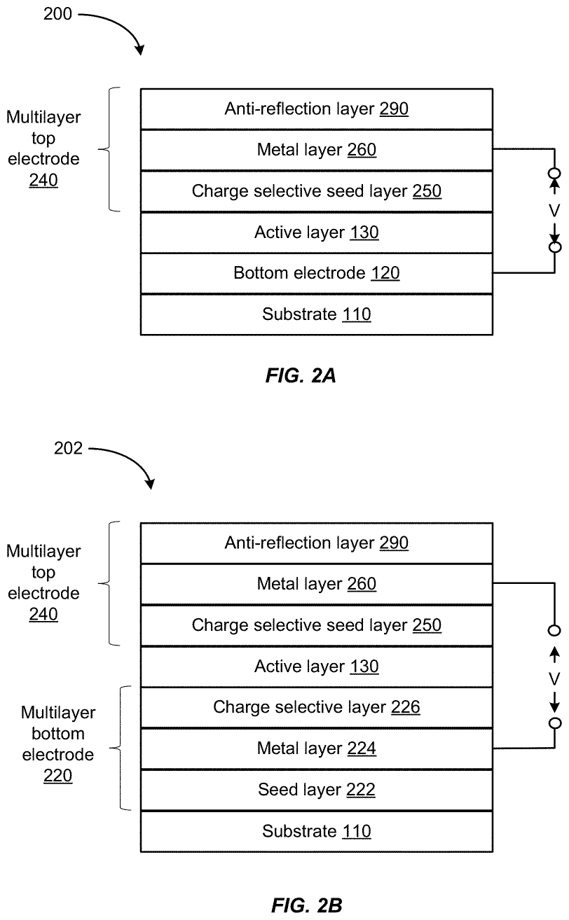

FIG. 2A shows a schematic cross-sectional view of a photovoltaic device 200 that includes a multilayer top electrode 240 with a single metal layer 260 according to some embodiments of the present invention. The multilayer top electrode 240 may include a charge selective seed layer 250, a metal layer 260, and an anti-reflection layer 290. Each of the charge selective seed layer 250, the metal layer 260, and the anti-reflection layer 290 may include a single layer or multiple layers (i.e., sublayers). Thus, the term “layer” as utilized in the specification does not necessarily connote a single unit of consistent material, but can include multiple sublayers to form a layer. As an example, an anti-reflection coating may consist of a single layer of material or multiple layers of different materials that form the coating. Accordingly, this coating, or other layers described herein may be referred to as a layer although the layer would include multiple sub-layers. The multilayer top electrode 240 may allow simultaneous optimization of electrical conductance and optical transmittance of the photovoltaic device 200, leading to improved AVT and sheet resistance values compared to other transparent electrodes, such as ITO, FTO, AZO or other transparent conductive oxides.

FIG. 2B shows a schematic cross-sectional view of a photovoltaic device 202 that includes a multilayer bottom electrode 220 paired with the multilayer top electrode 240 according to some embodiments of the present invention. The multilayer bottom electrode 220 may include a seed layer 222, a metal layer 224, and a charge selective layer 226. Each of the seed layer 222, the metal layer 224, and the charge selective layer 226 may include a single layer or multiple layers. The optional seed layer 222 may include oxides, sulfides, organic materials, refractory metals, or combinations thereof, that may promote conformal growth of the overlying thin metal layer. These seed layer 222 need not be conductive. However, using conductive layers may be beneficial in reducing the overall sheet resistance of the multilayer bottom electrode 220. The optional charge selective layer 226 may include oxides, sulfides, fluorides, metals and/or organic materials, such that the metal layer 224 is electrically-connected to the active layer 130 in the photovoltaic device 200.

According to some embodiments of the present invention, transparent photovoltaic devices may utilize a top electrode with multiple discrete metal layers spaced apart by interconnect layers to simultaneously optimize AVT/Tsol, emissivity and device performance.

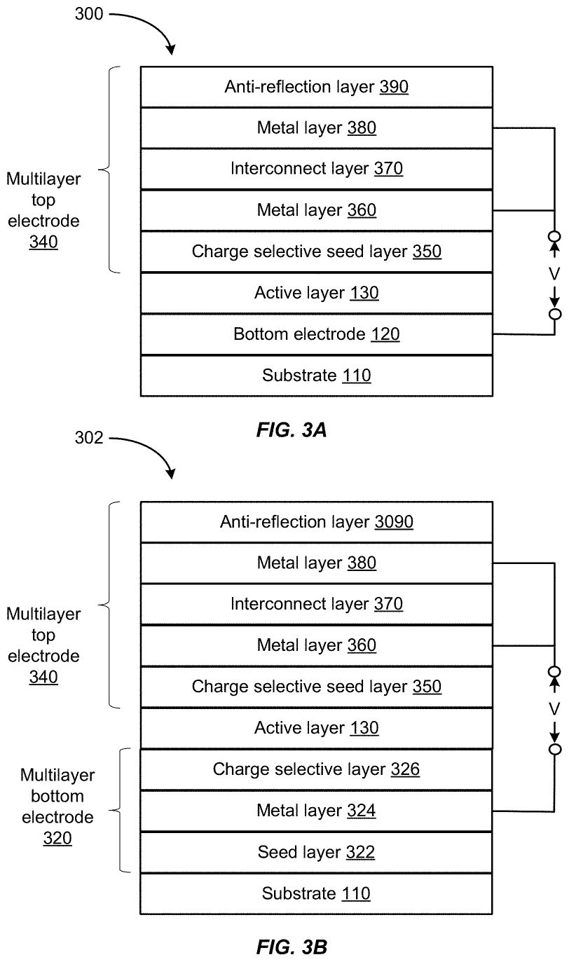

FIG. 3A shows a schematic cross-sectional view of a photovoltaic device 300 that includes a multilayer top electrode 340 with two metal layers 360 and 380 according to some embodiments of the present invention. The multilayer top electrode 340 may include a charge selective seed layer 350, a first metal layer 360, an interconnect layer 370, a second metal layer 380, and an anti-reflection layer 390. The anti-reflection layer 390 is optional. Each of the charge selective seed layer 350, the first metal layer 360, the interconnect layer 370, the second metal layer 380, and the anti-reflection layer 390 may include a single layer or multiple layers. The second metal layer can be similar to the first metal layer as described herein. As an example, the second metal layer can have a thickness ranging from 3 nm to 10 nm, 10 nm to 15 nm, 15 nm to 20 nm, 20 nm to 25 nm, or 25 nm to 30 nm.

FIG. 3B shows a schematic cross-sectional view of a photovoltaic device 302 that includes a multilayer bottom electrode 320 paired with the multilayer top electrode 340 according to some embodiments of the present invention. The multilayer bottom electrode 320 may include a seed layer 322, a metal layer 324, and a charge selective layer 326.

The properties and functions of the various layers in a multilayer electrode are discussed in more detail below.

The charge selective seed layer may include a single layer or multiple layers. The charge selective seed layer is preferably conductive and has electronic properties suitable as a charge carrier transport layer. When serving as an electron transport layer, the layer within the charge selective seed layer adjacent to the active layer may have an electron affinity (EA) aligned with the active layer EA and a high electron mobility. These characteristics may allow electrons to flow through the layer, while holes are “blocked” and cannot go through. Such electron selective layers may comprise TPBi, Fullerenes, C60, C70, TPBi:C60, BCP, BPhen, PEI, PEIE, NTCDI, NTCDA, PTCBI, fluorides such as LiF, ZnO, TiO₂, and combinations and derivatives thereof. When serving as a hole transport layer, the layer within the charge selective seed layer adjacent to the active layer may have an ionization potential (IP) aligned with the active layer IP and a high hole mobility. A hole transport layer may allow holes to flow through the layer while electrons are “blocked.” Such hole selective layers may comprise HAT-CN, TAPC, Spiro-OMeTAD, NPB, NPD, TPTPA, MoO₃, WO₃, V₂O₅ and combinations and derivatives thereof.

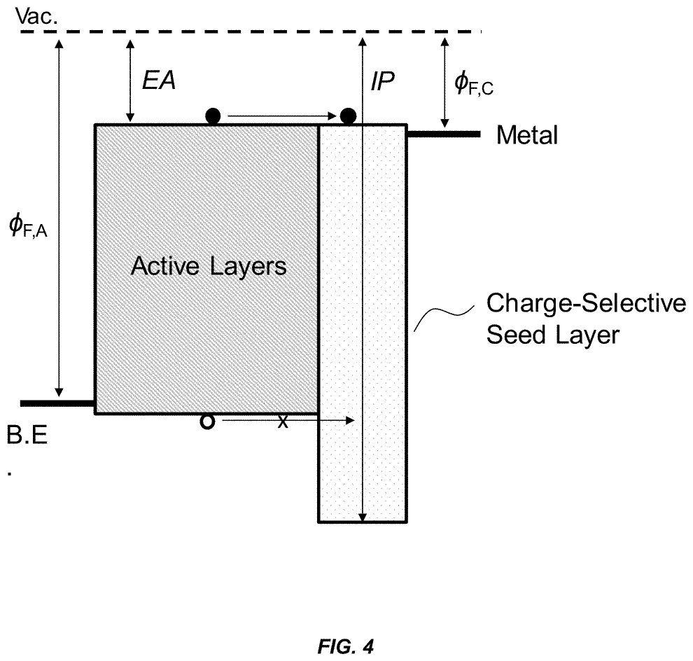

FIG. 4 shows a schematic energy level diagram whereby the charge selective seed layer functions as an electron transport layer within a transparent photovoltaic device according to some embodiments of the present invention. Work function of the cathode and anode are labeled as ϕ_{F,C} and ϕ_{F,A}, respectively. The EA of the charge selective seed layer is aligned with that of the active layer to allow electrons to flow through the layer. The IP of the charge selective seed layer is larger than that of the active layer such that holes are “blocked” from reaching the metal layer acting as a cathode.

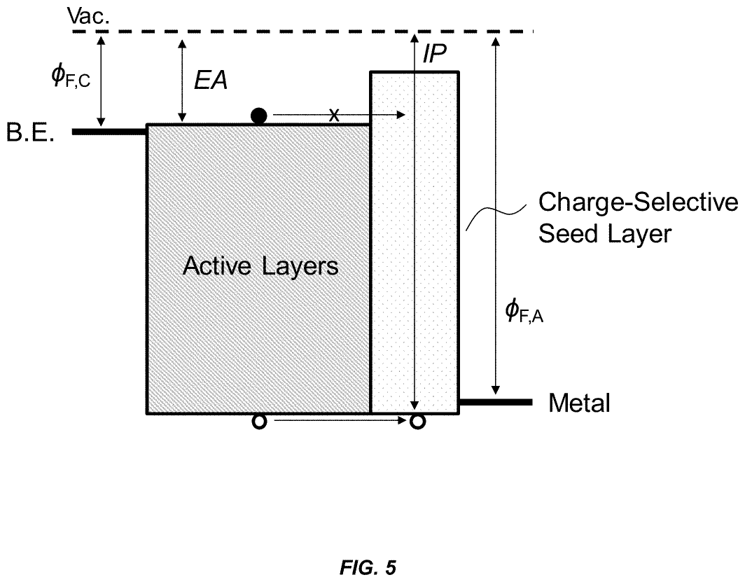

FIG. 5 shows a schematic energy level diagram whereby the charge selective seed layer functions as a hole transport layer within a transparent photovoltaic device according to some embodiments of the present invention. The IP of the charge selective seed layer is aligned with that of the active layer to allow holes to flow through the layer. The EA of the charge selective seed layer is smaller than that of the active layer such that electrons are “blocked” from reaching the metal layer acting as an anode.

The top surface of the charge selective seed layer may be characterized by a relatively low interfacial energy with the overlying metal layer. Lowering the free energy of the charge selective seed-metal interface promotes conformal growth of the overlying metal layer (as opposed to island formation or three-dimensional growth). In some embodiments, the properties of the charge selective seed layer may lead to a surface roughness of the overlying metal layer that is less than about 50% of its thickness. Such top surface layers may comprise ZnO, AZO, ITO, SnO₂, sulfides such as ZnS, refractory metal layer (e.g., 1-2 nm) such as Ti, Cr, Ni, and Ni:Cr, and organic semiconductors such as those listed above. Multilayer charge selective seeds may include combinations of layers, such as TPBi:C60/ZnO, TPBi:C60/ITO, TPBi:C60/AZO, TPBi:C60/SnO₂, HATCN/MoO₃, ZnO/Cr, TiO₂/Ni:Cr etc., as discussed above.

In some embodiments, the charge selective seed layer may be characterized by a relatively low optical extinction coefficient (k) such that parasitic absorption is minimized. The charge selective seed layer may be configured to improve the AVT of the entire photovoltaic device by tuning the optical field profile within the active layers. For example, the index (or indices) of refraction of the constituents of the charge selective seed layer and their thicknesses may be tailored to achieve this effect. In cases where k of the seed is not minimized, its absorption features may be tuned to achieve a desired color for the photovoltaic device stack. The charge selective seed layer may have a thickness ranging from about 1 nm to about 100 nm.

The charge selective seed layer may be deposited by vacuum thermal evaporation (VTE), organic vapor phase deposition (OVPD), electron beam physical vapor deposition (EBPVD), sputtering, atomic layer deposition (ALD), chemical vapor deposition (CVD), or solution processing.

Each metal layer may include a single layer or multiple layers. Each metal layer may include a pure metal such as Ag, Au, Al, or Cu, or doped metals such as Al:Ag and Sn:Ag, or combinations thereof. In some embodiments, the doping concentration may be less than about 10%. Ag may be advantageously used, as Ag provides less parasitic absorption and higher visible transmission as compared to other metals. Each metal layer may be deposited by sputtering, VTE, EBPVD, CVD, or solution processing.

The metal layers may have the highest conductivity among the various layers of the multilayer top electrode. Thus, the metal layers may provide the dominant paths for lateral charge conduction in the multilayer top electrode. Each metal layer may be characterized by a relatively low sheet resistance. For example, the sheet resistance of each metal layer may be less than about 100 Ohm/sq. The sheet resistance of the metal layers can be less than 50 Ohm/sq, less than 30 Ohm/sq, less than 20 Ohm/sq, less than 10 Ohm/sq, or less than 5 Ohm/sq. In a particular embodiment, the sheet resistance of the metal layers ranges from 1 Ohm/sq to 10 Ohm/sq.

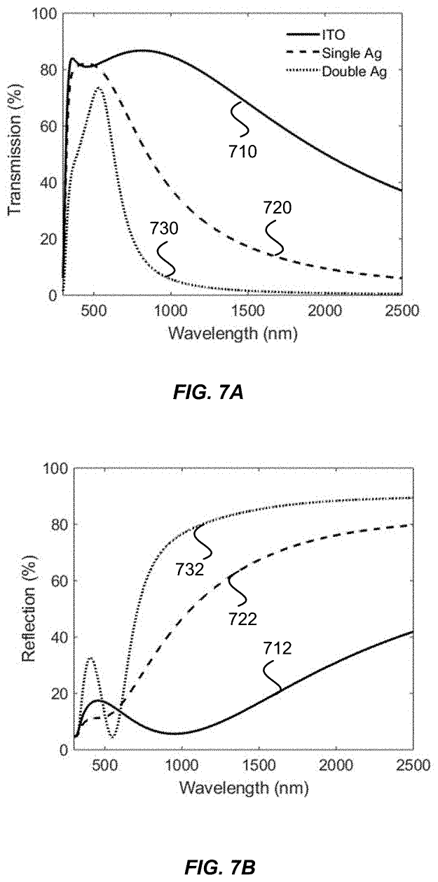

The use of metals in the multilayer top electrodes may provide relatively high reflection in the NIR and IR wavelength range, so that NIR/IR light may be reflected back into the active layer for a second pass, thereby increasing total absorption of the NIR/IR light by the active layer, as discussed below with respect to FIGS. 7A-7B and 8. As a result, the Jsc may be selectively enhanced in this wavelength range.

The use of metal layers may reduce the emissivity (e.g., below about 0.2) and increase the AVT/Tsol (e.g., greater than 1.4) of the photovoltaic device. The high IR reflectivity of the metal layers leads to a low thermal re-radiation efficiency, and hence low emissivity values. The high NIR reflectivity reduces the Tsol while maintaining a high AVT. This results in a high ratios of AVT/Tsol of the photovoltaic device.

Each metal layer may have a thickness ranging from about 5 nm to about 30 nm. In general, increasing thickness may result in decreased AVT and decreased emissivity, while reducing the sheet resistance of the multilayer top electrode. Therefore, for a transparent photovoltaic device, there may be a tradeoff between AVT and Rₜₕ/Tsol/emissivity. By exploiting the optical properties of the multilayer top electrode, this tradeoff may be mitigated.

Each interconnect layer may function as an optical spacer between two neighboring metal layers, and may help create resonant mode(s) in the multilayer top electrode so that it preferentially transmits visible light while rejecting UV and NIR/IR wavelengths. As such, the interconnect layers may help increase the ratio of AVT/Tsol of the multilayer top electrode. The interconnect layers may be characterized by relatively low k values in the visible wavelength range (e.g., from about 400 nm to about 700 nm), such that parasitic absorption is minimized. Multiple layers may be used in combination to tailor the transmitted and reflected color, the AVT, the Tsol and the AVT/Tsol of the photovoltaic device.

Each interconnect layer may include a single layer or multiple layers and may have a thickness ranging from about 5 nm to about 100 nm. Each interconnect layer may include conductive oxides (e.g., ITO, ZnO, AZO, IZO, TiO₂, WO₃, MoO₃, V₂O₅, NiO and SnO₂), sulfides such as ZnS or organic materials such as PEDOT:PSS, HAT-CN, TAPC, NTCDI, NTCDA, and TPBi, or combinations and derivatives thereof. Each interconnect layer may be deposited by sputtering, VTE, EBPVD, ALD, CVD, or solution processing.

Similar to the charge selective seed layer, the top surface of the interconnect layer may be characterized by relatively low interfacial energy with the overlying metal layer so as to promote conformal growth of the overlying metal layer. Each interconnect layer may include a thin metal layer (e.g., 1-2 nm), such as Ti, Cr, Ni, or NiCr, to promote adhesion of the adjacent metal layer to the interconnect layer.

The interconnect layers may have some electrical conductivity to provide a vertical charge conduction path between two neighboring metal layers. As such, the overall sheet resistance of the multilayer top electrode with multiple metal layers may be reduced below that of a multilayer top electrode with only the first metal layer. The reduced sheet resistance may result in lower emissivity values. Because each interconnect layer is relatively thin (e.g., 5-100 nm thick), the resistance of the interconnect layer in the vertical direction, may still be reasonably low to result in a relatively low overall sheet resistance of the multilayer top electrode.

The anti-reflection layer may include a single layer or multiple layers. In some embodiments of the present invention, the anti-reflection layer may include oxides such as SiO₂, ITO, ZnO, AZO, IZO, TiO₂, WO₃, MoO₃, V₂O₅, SnO₂, NiO, Al₂O₃, Nb₂O₅ and HfO₂, organics such as HAT-CN, TAPC, BCP, BPhen, TPBi, NTCDI, and NTCDA and combinations and derivatives thereof, sulfides such as ZnS or nitrides such as Si₃N₄ and AlN. The anti-reflection layer may be deposited by sputtering, VTE, EBPVD, ALD, CVD, or solution processing.

The anti-reflection layer may also function as a protection layer for improving the lifetime of the photovoltaic cell. Thus, the anti-reflection layer may have desired barrier properties against oxygen and moisture ingress into the underlying layers. The anti-reflection layer may also serve as a cap layer for improving the mechanical durability of the photovoltaic device.

The anti-reflection layer may be characterized by n>1.0 from about 400 nm to about 700 nm with a higher index of refraction in the visible wavelength range leading to improved AVT and reduced reflection of the photovoltaic device. The anti-reflection layer may have relatively low k values in the visible wavelength range from about 400 nm to about 700 nm such that parasitic absorption is minimized. But this is not required. The anti-reflection layer may also be used to tune the transmitted or reflected colors of the photovoltaic device. For example, the anti-reflection layer may be used as a color neutralizing layer.

Multilayer top electrodes that include a single metal layer (e.g., the multilayer top electrode 240 of the photovoltaic device 200 as illustrated in FIG. 2A) or with multiple metal layers (e.g., the multilayer top electrode 340 of the photovoltaic device 300 as illustrated in FIG. 3A) may allow simultaneous optimization of electrical conductance and optical transmittance of a photovoltaic device, leading to improved AVT and sheet resistance values compared to other transparent electrodes, such as ITO, FTO, AZO or other transparent conductive oxides.

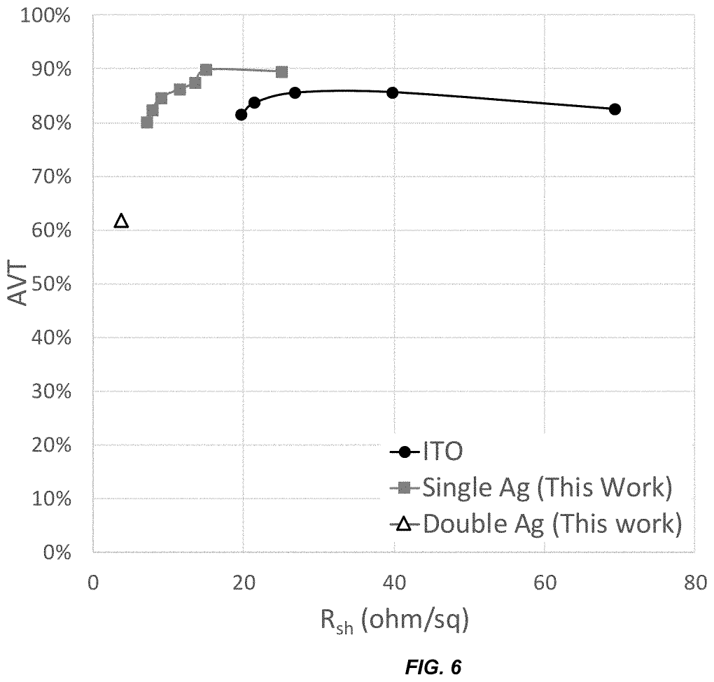

FIG. 6 shows experimental values for AVT vs. sheet resistance for various types of top electrodes configurations according to some embodiments. As illustrated, multilayer top electrodes with a single Ag layer (represented by square symbols in FIG. 6) or with two Ag layers (represented by a triangle symbol in FIG. 6) can exhibit improved sheet resistance compared to those of ITO electrodes (represented by the circle symbols in FIG. 6), while maintaining high AVT. The low sheet resistance of the multilayer top electrode is enabled by the high intrinsic conductivity of Ag compared to ITO. The high AVT of the multilayer top electrode is achieved by engineering the optical properties and thicknesses of the layers comprising the multilayer top electrode. By using multiple metal layers spaced apart by interconnect layers, optical interference may be exploited to produce higher AVT values than what's possible in a multilayer electrode with a single metal layer and having the combined thickness of the multiple metal layers. By using electrically conducting interconnect layers, the overall sheet resistance can be reduced below that of a multilayer top electrode employing a single metal layer exhibiting the same AVT. The multilayer electrode with multiple metal layers may efficiently transmit visible light while reflecting near-infrared (NIR) wavelengths (e.g., >700 nm), such that NIR-absorption of the underlying active layer may be preferentially enhanced in transparent photovoltaic devices. Increased reflectivity in NIR wavelengths may decrease the operating temperature of the photovoltaic device by reducing parasitic absorption in the electrodes. As illustrated in FIG. 6, the top electrode sheet resistance can be less than 50 Ohm/sq, less than 20 Ohm/sq, less than 10 Ohm/sq, or less than 5 Ohm/sq. In a particular embodiment, the top electrode sheet resistance ranges from ranges from 1 Ohm/sq to 10 Ohm/sq.

FIG. 7A shows simulated transmission curves vs. wavelength for a commercial ITO electrode (solid line 710), a multilayer electrode with a single Ag layer (dashed line 720), and a multilayer electrode with two Ag layers (dotted line 730), according to some embodiments of the present invention. As illustrated, the transmission values in the NIR and IR wavelength range (e.g., from about 700 nm to about 2500 nm) of the multilayer electrode with a single Ag layer (dashed line 720) are decreased significantly as compared to those of the ITO electrode (solid line 710). The NIR/IR transmission is further reduced in the multilayer electrode with two Ag layers (dotted line 730). The transmission windows of the multilayer electrode with a single Ag layer and the multilayer electrode with two Ag layers overlap well with the photopic response curve of the human eye with a peak at about 550 nm.

FIG. 7B shows simulated reflection curves vs. wavelength for the commercial ITO electrode (solid line 712), the multilayer electrode with a single Ag layer (dashed line 722), and the multilayer electrode with two Ag layers (dotted line 732), according to some embodiments of the present invention. As illustrated, the reflection values in the NIR and IR wavelength range of the multilayer electrode with a single Ag layer (dashed line 722) are increased significantly as compared to those of the ITO electrode (solid line 712). The NIR/IR reflection is further increased in the multilayer electrode with two Ag layers (dotted line 732). The increased reflection in the NIR and IR wavelengths may lead to enhanced absorption within the underlying active layers, as light in those wavelengths may be reflected back toward the active layer for a second pass. Therefore, the Jsc of the photovoltaic device may be preferentially increased at these wavelengths. The increased reflection in the NIR/IR wavelengths may also lead to decreased operating temperature of the photovoltaic device by reducing parasitic absorption in the electrode. This is important for minimizing thermal radiated power from the photovoltaic cell, which scales with the fourth power of the operating temperature.

The interconnect layer sandwiched between the two metal layers may form an optical cavity and support a Fabry-Perot resonance. The resonance wavelength of the cavity may be tuned to coincide with the photopic response of the human eye in the visible spectrum. Due to the thinness of the metal layers (typically less than about 30 nm), the quality factor (the full-width-half-maximum) of the transmitted mode supported by the cavity may be relatively broad. The quality factor may be adjusted such that the transmitted mode spans the visible spectrum, resulting in a high AVT of the stack. By tuning the thicknesses and the refractive indices of the interconnect layer within the cavity and the anti-reflection layers, the color and shape of the transmission spectrum may be engineered to maximize AVT, while rejecting wavelengths outside of the resonance condition (e.g., UV and NIR light).

In some embodiments, more than two metal layers and more than one interconnect layers may be used in a top electrode. Introducing additional interconnect/metal layers may allow further tuning of the color of the stack by introducing additional resonant modes for transmission. Rejected wavelengths may then be reflected back through the active layer, with some of their optical power absorbed by the active layer during the second pass.

FIG. 8 illustrates schematically a reflection spectrum 810 vs. wavelength (solid line 810) of a multilayer top electrode. As illustrated, the reflection spectrum 810 may be tuned to exhibit minimal reflection in the visible wavelength range, while exhibiting high reflection values outside the visible wavelength range. The dashed line 820 illustrates a “flat” and broad absorption profile of a non-selective active layer, extending from the ultraviolet (UV) into the NIR. Because the multilayer top electrode preferentially reflects UV and NIR light back to the active layer for a second pass, the absorption by the active layer in the UV and NIR wavelengths may be selectively enhanced, as illustrated schematically by the dotted line 830. Thus, the photocurrent generated by the photovoltaic device at wavelengths outside the visible spectrum may be enhanced. The same concept may be applied to an active layer with inherently selective absorption in the UV and NIR to further enhance the absorption strength of such layers in the UV and NIR while maintaining high AVT.

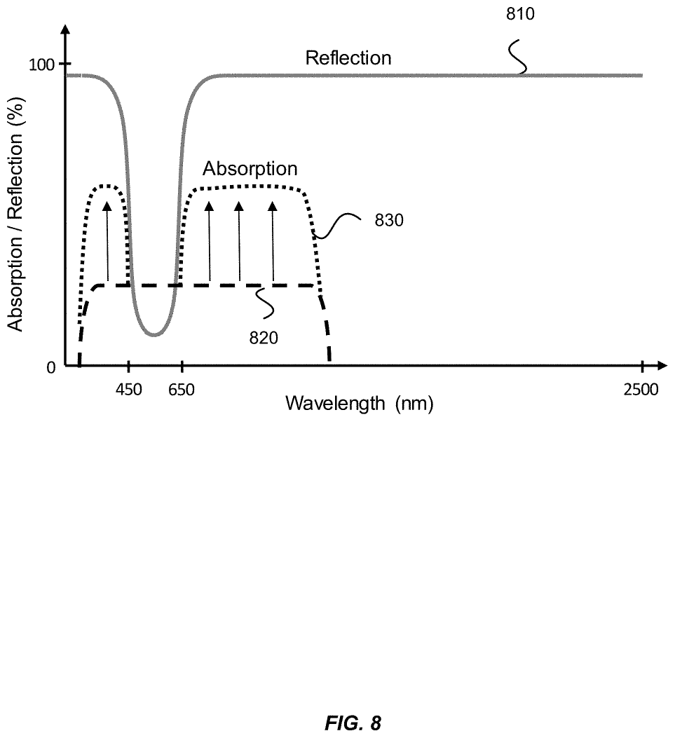

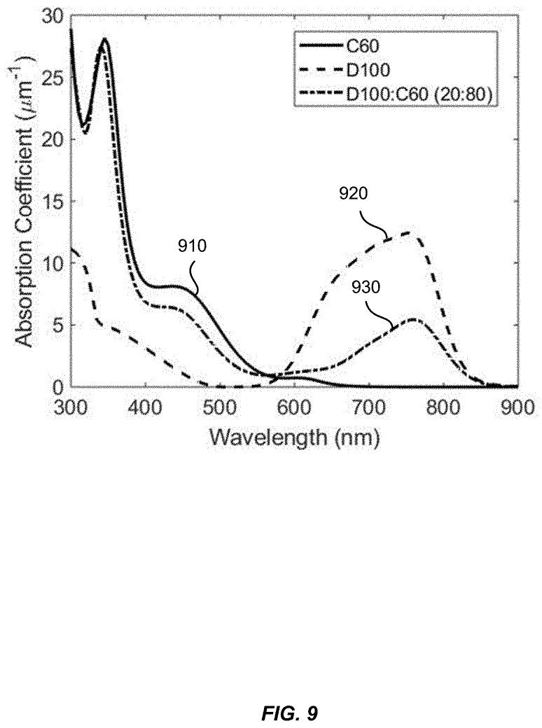

FIG. 9 shows exemplary spectra 910, 920, and 930 of absorption coefficients for OPV active layers that comprise D100, C60, and a D100:C60 blend, respectively, according to some embodiments of the present invention. D100 is an organic semiconducting electron donor material with peak absorption in the NIR. C60 is an electron acceptor material. These active layer materials include “selective” organic materials whose extinction coefficients are peaked outside of the visible wavelength range. As an example, OPV devices with the following structure are considered: glass|bottom electrode|D100:C60 (20:80) (60 nm)|C60 (10 nm)|top electrode, with a variety of bottom electrode and top electrode configurations.

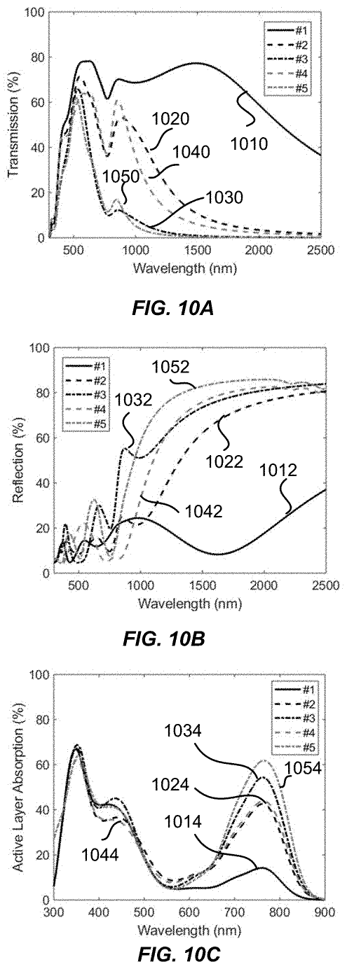

FIG. 10A shows transmission curves vs. wavelength of various OPVs obtained from simulations using the above structure. FIG. 10B shows reflection curves vs. wavelength of the various OPVs obtained from simulations. FIG. 10C shows the active layer absorption vs. wavelength of the various OPVs obtained from simulation.

Referring to FIG. 10A, the curve 1010 is the transmission curve for a photovoltaic device that includes an ITO bottom electrode and an ITO top electrode without any metal layer (Stack #1). The curve 1020 is the transmission curve for a photovoltaic device that includes an ITO bottom electrode and a multilayer top electrode with a single Ag layer (Stack #2). The curve 1030 is the transmission curve for a photovoltaic device that includes an ITO bottom electrode and a multilayer top electrode with two Ag layers (Stack #3). As illustrated, the transmission in the NIR wavelengths is significantly reduced in the photovoltaic device that includes a multilayer top electrode with a single Ag layer (curve 1020) as compared to the photovoltaic device that includes a ITO top electrode (curve 1010), and is further reduced in the photovoltaic device that includes a multilayer top electrode with two Ag layers (curve 1030).

As illustrated in FIG. 10B, the reflection in the NIR wavelengths is increased in the photovoltaic device that includes a multilayer top electrode with a single Ag layer (curve 1022) as compared to photovoltaic device that includes a ITO top (curve 1012), and is further increased in the photovoltaic device that includes a multilayer top electrode with two Ag layers (curve 1032).

As illustrated in FIG. 10C, as a result of the increased reflection from the multilayer top electrodes, the absorption by the active layer is increased in the photovoltaic device that includes a multilayer electrode with a single Ag layer (curve 1024) as compared to the photovoltaic device that includes an ITO top electrode (curve 1014), and is further increased in the photovoltaic device that includes a multilayer electrode with two Ag layers (curve 1034).

The multilayer top electrode may be paired with various types of bottom electrodes according to various embodiments. For example, the bottom electrode may include a transparent conducting oxide, a multilayer stack with a single metal layer, or an alternative transparent electrode such as graphene, carbon nanotube network, Ag nanowire network, and the like.

As illustrated in FIGS. 2B and 3B, multilayer bottom electrodes 220 or 320 that include one or more metal layers may also be used in photovoltaic devices. There may be numerous advantages of using a multilayer bottom electrode when paired with a multilayer top electrode. For example, the optical electric field within the active layer may be enhanced as compared to alternative bottom electrode structures, resulting in improved active layer absorption and photocurrent generation. It may also be possible to achieve simultaneous optimization of electrical conductance and optical transmittance, leading to optimal AVT and sheet resistance values as compared to other transparent bottom electrodes. In addition, reflection in the NIR wavelengths of the transparent photovoltaic device may be increased, so that the integrated solar absorption may be reduced at wavelengths outside the active layer absorption spectrum. This may lead to reduced operating temperature of the transparent photovoltaic device under solar illumination. As building-integrated photovoltaic devices, lower operating temperatures may reduce the re-radiated power (blackbody emission) into the building, improve thermal insulation, and reduce the probability of failure of the underlying glass substrate due to shading temperature differential across the window unit.

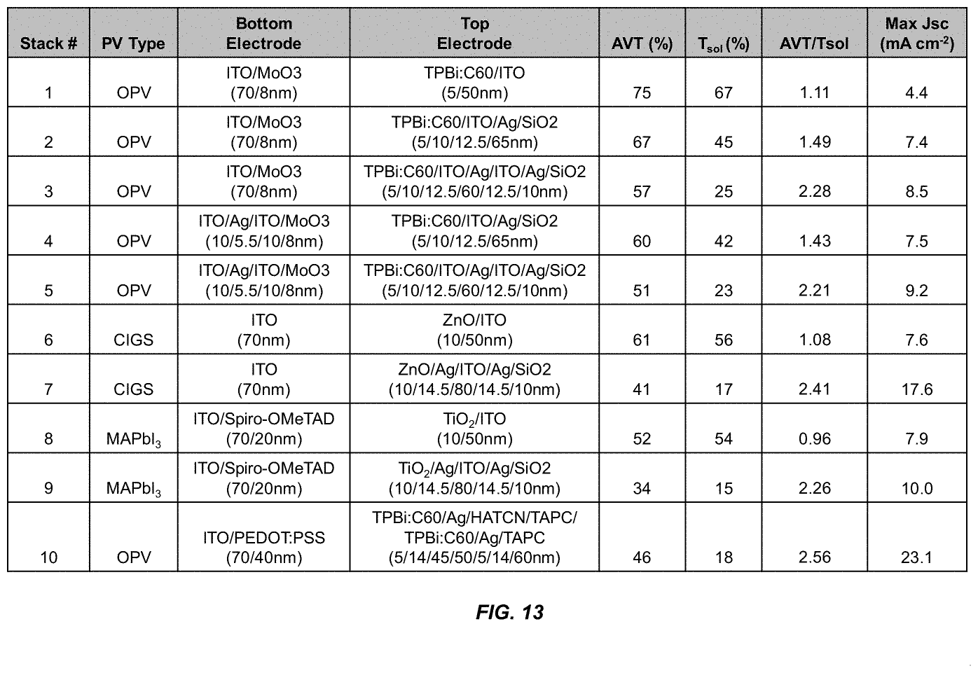

Referring again to FIGS. 10A-10C, FIG. 10A shows a simulated transmission curve 1040 for an OPV that includes a multilayer bottom electrode with a single Ag layer paired with a multilayer top electrode with a single Ag layer (curve 1040, Stack #4 shown in FIG. 13), and a simulated transmission curve 1050 for an OPV that includes a multilayer bottom electrode with a single Ag layer paired with a multilayer top electrode with two Ag layers (Stack #5 shown in FIG. 13). As illustrated, by pairing a multilayer bottom electrode with a multilayer top electrode, the transmission in the NIR is further reduced as compared to that of the OPV device with an ITO bottom electrode paired with the multilayer top electrode.

FIG. 10B shows a simulated reflection curve 1042 for the OPV that includes the multilayer bottom electrode with a single Ag layer paired with either a multilayer top electrode with a single Ag layer (Stack #4 shown in FIG. 13), and simulated reflection curve 1052 for the OPV that includes the multilayer bottom electrode with a single Ag layer paired with a multilayer top electrode with two Ag layers (Stack #5 shown in FIG. 13). As illustrated, by pairing a multilayer top electrode with a multilayer bottom electrode, the reflection in the NIR is enhanced as compared to that of the OPV device with an ITO bottom electrode paired with the multilayer top electrode.

FIG. 10C shows a simulated absorption curve 1044 for the OPV that includes the multilayer bottom electrode with a single Ag layer paired with a multilayer top electrode with a single Ag layer (Stack #4 shown in FIG. 13), and simulated absorption curve 1054 for the OPV that includes the multilayer bottom electrode with a single Ag layer paired with a multilayer top electrode with two Ag layers (Stack #5 shown in FIG. 13). As illustrated, by pairing a multilayer top electrode with a multilayer bottom electrode, the absorption in the NIR is enhanced as compared to that of the OPV device with an ITO bottom electrode. The multilayer bottom electrode with a single Ag layer may help establish a stronger optical cavity within the active layer which can lead to improved active layer absorption.

Multilayer top electrodes that include one or more metal layers may also be used with inorganic active layers in photovoltaic devices to achieve similar advantages. As examples, two inorganic photovoltaic devices that have the following structure are considered: glass|ITO (70 nm)|CuIn_{0.69}Ga_{0.31}Se (30 nm)|top electrode.

The active layer includes CuIn_{0.69}Ga_{0.31}Se (CIGS) and has a thickness of 30 nm. The bottom electrode includes ITO and has a thickness of 70 nm. A first photovoltaic device has a 10 nm ZnO/50 nm ITO top electrode (Stack #6 as shown in FIG. 13). ZnO is included to act as a charge selective transport layer. A second photovoltaic device has a 10 nm ZnO/14.5 nm Ag/80 nm ITO/14.5 nm Ag/10 nm SiO₂ top electrode (Stack #7 shown in FIGS. 13A-B).

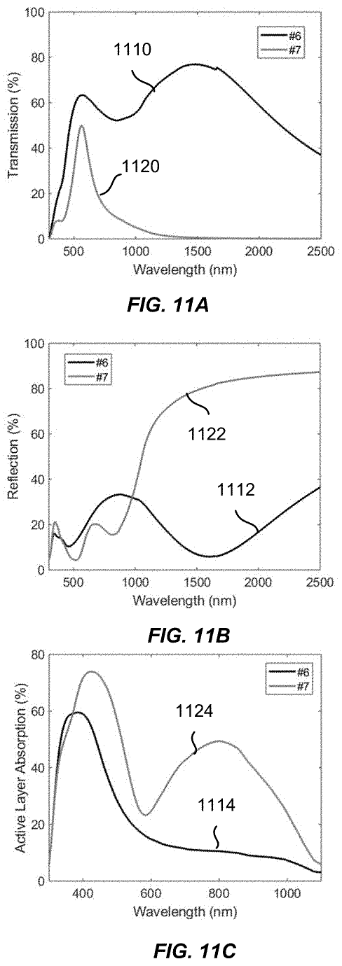

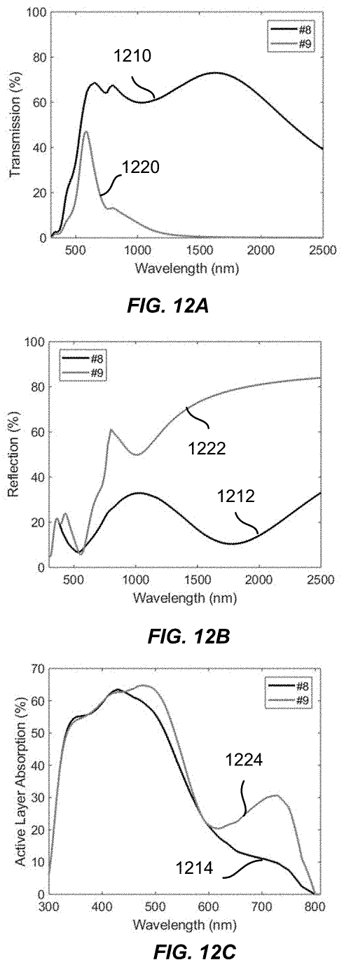

FIG. 11A shows simulated transmission curves 1110 and 1120 vs. wavelength for two electrode configurations used in inorganic photovoltaic devices that include CIGS in the active layer according to some embodiments of the present invention. FIG. 11B shows simulated reflection curves 1112 and 1122 vs. wavelength for the two electrode configurations used in the inorganic photovoltaic devices that include CIGS in the active layer according to some embodiments of the present invention. FIG. 11C shows simulated active layer absorption curves 1114 and 1124 vs. wavelength for the two electrode configurations used in the inorganic photovoltaic devices that include CIGS in the active layer according to some embodiments of the present invention.

The CIGS active layer is intrinsically “non-selective.” That is, the extinction coefficient is relatively “flat” from the visible to NIR wavelengths (e.g., from about 500 nm to about 900 nm), as illustrated in FIG. 11C (curve 1114). When using a multilayer top electrode with two Ag layers, the active layer becomes “selective” in that the active layer absorption exhibits a strong peak at about 800 nm in the NIR, as illustrated in FIG. 11C (curve 1124). As a result, the Jsc of the photovoltaic cell is significantly increased while maintaining transparency.

Thus, effectively, the multilayer top electrode with two Ag layers causes the CIGS to become a “selective” absorber with absorption peaks outside the visible spectrum. This is a result of the preferential enhancement of absorption in the NIR and UV due to increased reflectivity of the multilayer top electrode with two Ag layers at those wavelengths (as illustrated by the curve 1122 shown in FIG. 11B), as compared to that of the photovoltaic device that includes a ZnO/ITO top electrode (as illustrated by the curve 1112 shown in FIG. 11B). As illustrated in FIG. 11A, the increased reflectance of in the NIR wavelengths is accompanied by a decrease of transmission in the NIR wavelengths (as illustrated by the curve 1120 as compared to the curve 1110). The reduction in NIR/IR transmission significantly decreases the Tsol of the photovoltaic cell while maintaining a high AVT, leading to an increase in the ratio of AVT/Tsol.

Multilayer top electrodes that include one or more metal layers may also be used with inorganic active layers in photovoltaic devices to achieve similar advantages. As examples, two inorganic photovoltaic devices that have the following structure are considered: Glass ITO (70 nm)|Spiro-OMeTAD (20 nm)|MAPbI₃ (60 nm)|Top Electrode.

The active layer includes MAPbI₃ and has a thickness of 60 nm. Spiro-OMeTAD is used as a hole transporting layer. The bottom electrode includes ITO and has a thickness of 70 nm. A first photovoltaic device has a 10 nm TiO₂/50 nm ITO top electrode (Stack #8 as shown in FIG. 13). TiO₂ is included to act as a charge selective transport layer. A second photovoltaic device has a 10 nm TiO₂/14.5 nm Ag/80 nm ITO/14.5 nm Ag/10 nm SiO₂ top electrode (Stack #9 shown in FIG. 13).

FIG. 12A shows simulated transmission curves 1210 and 1220 vs. wavelength for two electrode configurations used in photovoltaic devices that include MAPbI₃ perovskite in the active layer according to some embodiments of the present invention. FIG. 12B shows simulated reflection curves 1212 and 1222 vs. wavelength for the two electrode configurations used in the photovoltaic devices that include MAPbI₃ perovskite in the active layer according to some embodiments of the present invention. FIG. 12C shows simulated active layer absorption curves 1214 and 1224 vs. wavelength for the two electrode configurations used in the photovoltaic devices that include MAPbI₃ perovskite in the active layer according to some embodiments of the present invention. Here, again the multilayer top electrode that includes two Ag layers result in lower NIR transmission (the curve 1220 in FIG. 12A), higher NIR reflection (the curve 1222 in FIG. 12B), and a more “selective” active layer absorption (the curve 1224 in FIG. 12C), as compared to those of the photovoltaic device with a TiO₂/ITO top electrode (the curves 1210, 1212, and 1214 in FIGS. 12A, 12B, and 12C, respectively).

FIG. 13 is a table that summarizes the structure and properties of transparent photovoltaic devices comprising a variety of electrode and active layer combinations as discussed in relation to FIGS. 10A-10C, 11A-11C, and 12A-12C, according to various embodiments of the present invention. For values of AVT and Tₛₒₗ, the device transmission spectra were used. Using these values, the ratio of AVT over Tsol was calculated.

As shown in FIG. 13, the introduction of metal layers in the top electrode favorably reduces the Tsol while maintaining a high AVT leading to improved (AVT/Tsol) values. For example, Tsol values can be reduced below 50% while (AVT/Tsol) greater than 1.4 can be achieved by switching to multilayer top electrode. In addition, there is a concomitant enhancement in the Jsc of photovoltaic devices. Improvement in (AVT/Tsol) is important for architectural glass applications while higher Jsc is desired for improved photovoltaic device performance. The use of multilayer top electrodes simultaneously improves both of these metrics. This approach is generally applicable to any transparent photovoltaic device as highlighted by the comparisons between organic, CIGS and perovskite active layers shown in this work.

In some embodiments, it may be advantageous to incorporate a multilayer bottom electrode in place of ITO with a multilayer top electrode. This may lead to improvements in the Jsc of photovoltaic device as a result of optical cavity effects within the active layer. In some embodiments, this may also result in an improvement in (AVT/Tsol).

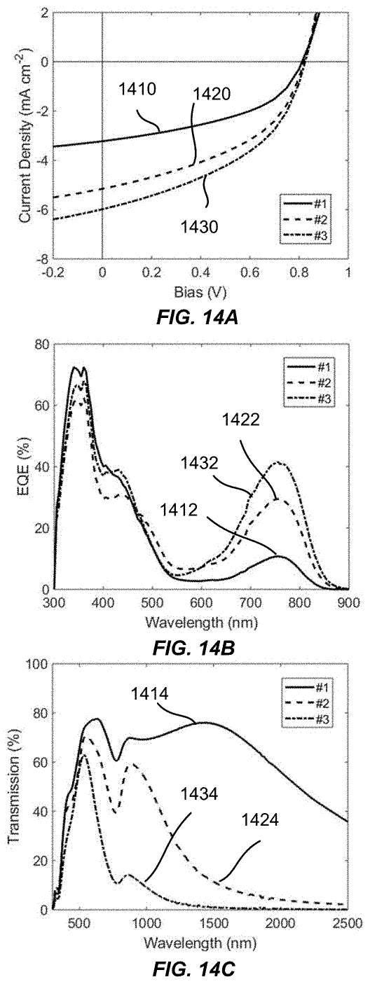

FIG. 14A shows experimental current density-voltage curves 1410, 1420, and 1430 of various OPVs tested under a solar simulator calibrated to AM1.5G illumination. The OPVs had device structures as defined by Stacks #1-#3 in FIG. 13A. FIG. 14B shows the corresponding external quantum efficiency (EQE) curves 1412, 1422, and 1432 vs. wavelength for Stacks #1-#3 obtained from experiment. FIG. 14C shows the corresponding transmission curves 1414, 1424, and 1434 vs. wavelength of the various OPVs obtained from experiment.

Referring to FIG. 14A, the photocurrent output from the OPV is significantly enhanced for the photovoltaic device that includes a multilayer top electrode with a single Ag layer (curve 1420) as compared to the photovoltaic device that includes a ITO top electrode (curve 1410), and is further increased in the photovoltaic device that includes a multilayer top electrode with two Ag layers (curve 1430).

As shown in FIG. 14B, due to the increased reflection from the multilayer top electrodes, the experimental EQE in the NIR is increased in the photovoltaic device that includes a multilayer electrode with a single Ag layer (curve 1422) as compared to the photovoltaic device that includes an ITO top electrode (curve 1412), and is further increased in the photovoltaic device that includes a multilayer electrode with two Ag layers (curve 1432). The increased EQE is a direct result of the increased active layer absorption in the photovoltaic devices that include a multilayer top electrode, as illustrated in FIG. 10C. FIG. 14C shows that the experimental transmission in the NIR wavelengths is significantly reduced in the photovoltaic device that includes a multilayer top electrode with a single Ag layer (curve 1424) as compared to the photovoltaic device that includes a ITO top electrode (curve 1414), and is further reduced in the photovoltaic device that includes a multilayer top electrode with two Ag layers (curve 1434). The measured spectra closely matches the corresponding simulated curves 1010, 1020, and 1030, respectively, as shown in FIG. 10A.

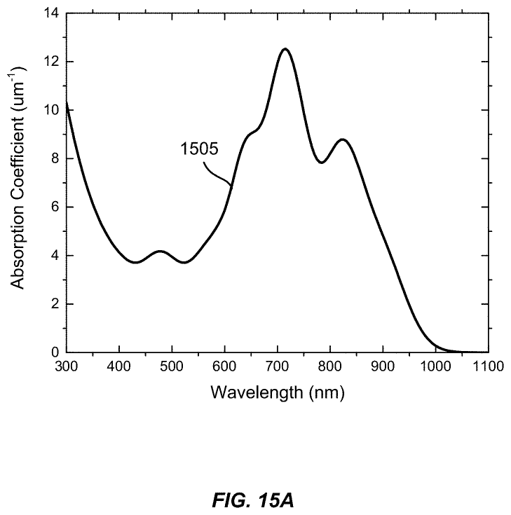

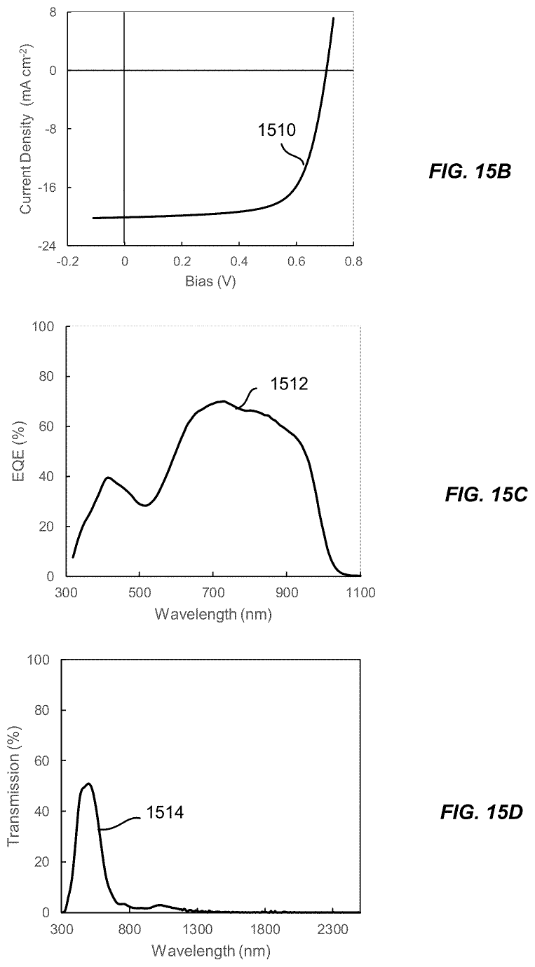

FIG. 15A shows absorption coefficient for OPV active layer corresponding to Stack #10 in FIG. 13. The active layer includes 100 nm of the organic active layer materials whose absorption coefficients are peaked outside of the visible wavelength range. Bottom and top electrode for this device are as defined in FIG. 13.

FIG. 15B shows an experimental current density-voltage curve 1510 for the OPV tested under a solar simulator calibrated to AM1.5G illumination. FIG. 15C shows the corresponding external quantum efficiency (EQE) curve 1512 vs. wavelength for Stacks #10 obtained from experiment. FIG. 15D shows the corresponding transmission curve 1514 vs. wavelength obtained from experiment.

As shown in FIG. 15C, a high experimental EQE is maintained in the NIR due to the selective NIR reflection of the multilayer electrode with two Ag layers (curve 1512). The increased EQE at NIR wavelengths is a direct result of the increased active layer absorption in the photovoltaic devices that include a multilayer top electrode. FIG. 15D shows that the experimental transmission in the NIR wavelengths is minimal in this device (curve 1514) beyond 700 nm.

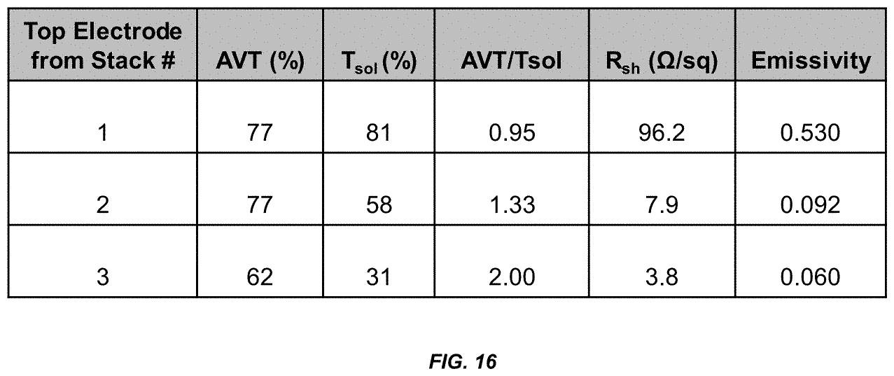

FIG. 16 is a table that summarizes the measured optical and electrical performance of a variety of top electrode configurations as discussed in FIGS. 10A-C, 14A-C, and 19B-C. The use of a multilayer top electrode can significantly lower the Tsol from that of ITO while maintaining a high AVT, resulting in (AVT/Tsol) values approaching 2.0. Simultaneously, the Rₛₕ can be reduced by an order of magnitude and the emissivity can be lowered to below a value of 0.1. For values of AVT and Tₛₒₗ, the top electrode transmission spectra were used.

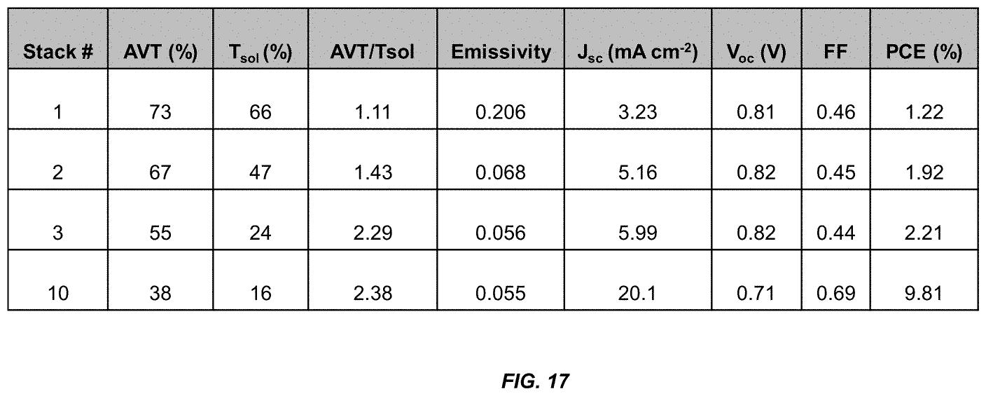

FIG. 17 is a table that summarizes the measured optical and electrical performance of transparent OPVs comprising a variety of electrode combinations as discussed in FIGS. FIGS. 10A-C, 14A-C, 15A-D, and 19B-C. For values of AVT and Tₛₒₗ, the device transmission spectra were used.

As shown in FIG. 17, the measured AVT, Tₛₒₗ and (AVT/Tsol) values of Stacks #1-#3 closely match the simulated values as shown in FIG. 13. Through the use of a multilayer top electrode with two Ag layers, Tsol can be lowered while maintaining a high AVT of the photovoltaic device, and (AVT/Tsol) values as high as 2.3 can be experimentally achieved. Simultaneously, the Jsc and power conversion efficiency (PCE) are significantly improved. By extending the multilayer top electrode concept to a higher efficiency OPV active layer using Stack #10, both a high PCE and (AVT/Tsol) can be simultaneously achieved.

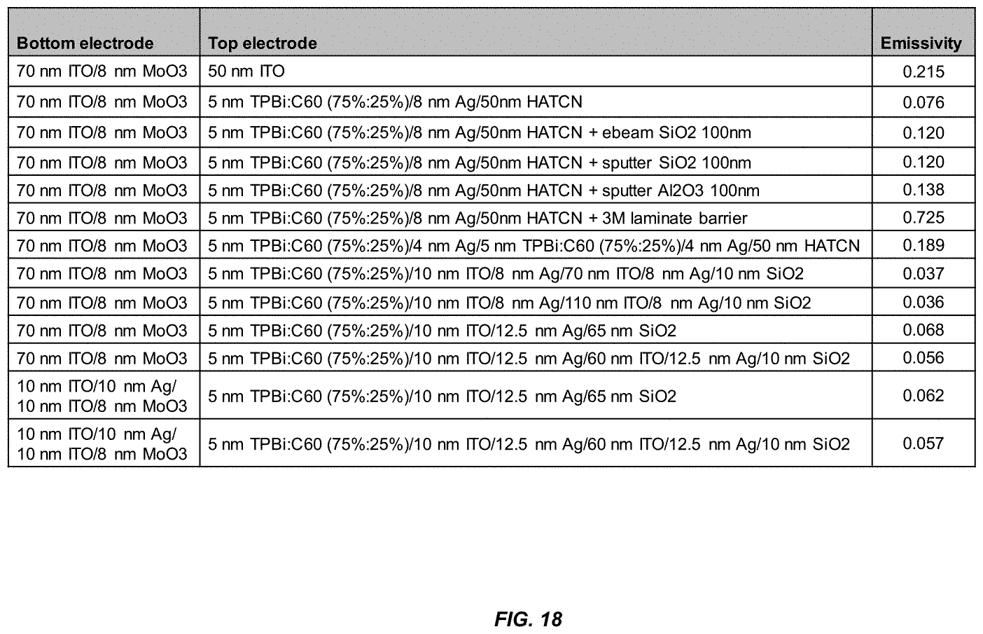

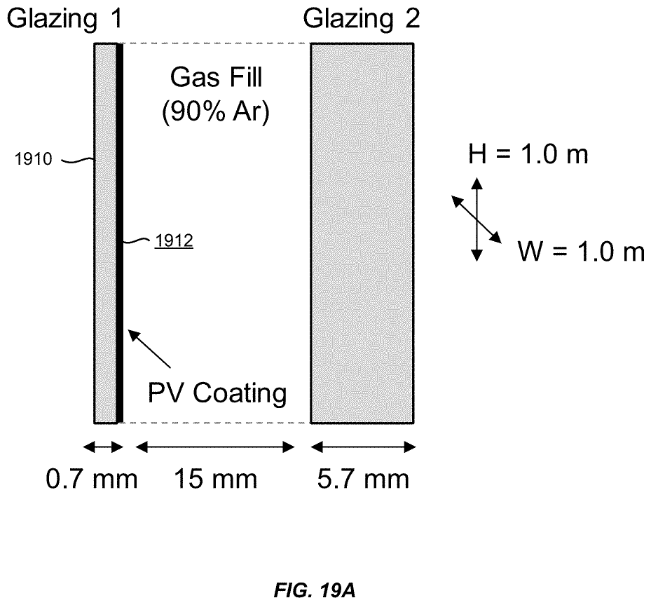

FIG. 18 is a table showing the experimental emissivity values of various organic photovoltaic devices with different electrode configurations according to various embodiments. Unlike transparent conductive oxides, multilayer electrodes with one or more metal layers can be engineered with near perfect IR reflection which leads to low thermal emissivity (referred to as low-e). Thus, a multilayer top electrode may provide dual functionality as a low-e coating and as a transparent electrode for a transparent photovoltaic device. When used for architectural glass applications, it may be desired that the emissivity, defined as the power re-radiated into the building by a transparent photovoltaic device (as a blackbody emitter), is as low as possible. By using multiple metal layers, the IR reflection of the top electrode may be reduced compared to a single ITO layer electrode or a multilayer top electrode with a single metal layer, and thus the emissivity may be minimized.

For architectural glass applications, a transparent photovoltaic device may be integrated into a window unit known as an insulated glass unit (IGU) that may include multiple panes of glass with a gas filled in the cavity between. The full IGU construction impacts heat flow through the window into a building. Thus, for such applications it is desirable to calculate a Solar Heat Gain Coefficient (SHGC) for the IGU. The SHGC is the fraction of incident solar radiation admitted through a window, and can be defined by the relation

SHGC=Tₛₒₗ+N·Aₛₒₗ

where Tₛₒₗ and Aₛₒₗ are the transmitted and absorbed fractions of the incident solar radiation through the IGU and N is the inward flowing fraction (both convective and radiative) of absorbed heat through the IGU. Selectivity is defined as the ratio of AVT of the IGU over SHGC (AVT/SHGC). Because Tsol is linearly related to SHGC, high values of AVT/Tsol generally correspond to high values of selectivity. Thus by engineering devices to have a high reflectivity in the NIR and IR, SHGC can be reduced. By maintaining a high AVT while rejecting as much non-visible light as possible, a transparent photovoltaic device can be engineered with a high selectivity, which is one of the performance metrics for low-E windows.

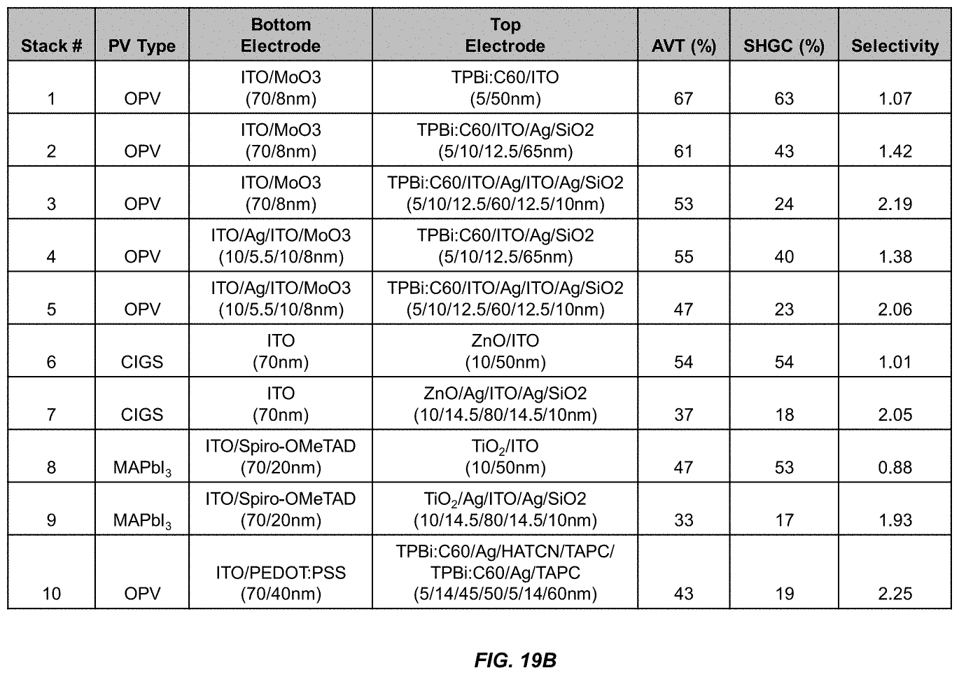

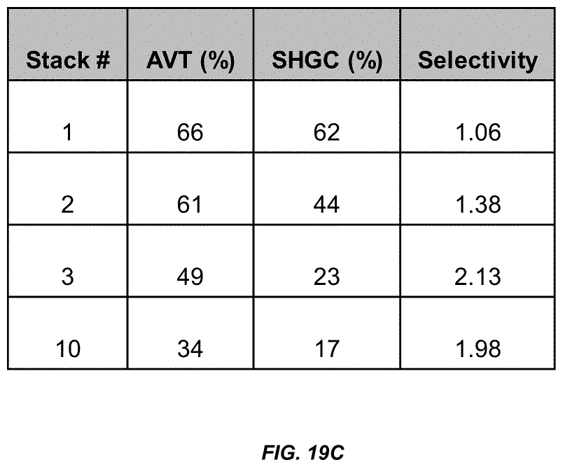

FIG. 19A is a schematic diagram of a simple insulated glass unit (IGU) construction assumed for calculating SHGC and selectivity values of the photovoltaic devices in the present invention. We note that in practice, the IGU construction may vary to include different thicknesses of glass, different spacer distances, and different gas composition. For the calculations herein, the photovoltaic coatings were applied on the second surface 1912 of glazing 1 1910, which acts as the glass substrate. In this diagram, light is incident from the left. SHGC and selectivity were calculated using Lawrence Berkeley National Lab's WINDOW software assuming NFRC 100-2010 environmental conditions, 90° tilt with no deflection, and considering center-of-glass values only (ignoring contributions from framing).

FIG. 19B is a table that summarizes the structures and properties (e.g., AVT, Solar Heat Gain Coefficient (SHGC) and selectivity values) of transparent photovoltaic devices with a variety of electrode and active layer combinations, as discussed in relation to FIGS. 10A-10C, 11A-11C, 12A-12C, and 15A-D, when integrated into an insulated glass unit according to FIG. 19A, according to various embodiments of the present invention. For SHGC and selectivity, the IGU values were calculated from the simulated spectra as described above. For simulated device structures employing an ITO top electrode (stacks 1, 6, and 8), a single Ag layer-containing top electrode (stacks 2 and 4), and a double Ag layer-containing top electrode (stacks 3, 5, 7, 9, and 10), emissivity values of 0.2, 0.1, and 0.05 were assumed, respectively.

As shown in FIG. 19B, the introduction of metal layers in the top electrode reduces the SHGC while maintaining a high AVT leading to improved selectivity values. For some embodiments, SHGC values less than 45% can be achieved while maintaining AVT>60% allowing selectivity values greater than 1.4

Note that, for a fixed photovoltaic cell selectivity, higher AVT values may be expected in intrinsically “selective” active layers (i.e., preferentially UV/NIR absorbing materials). This may be due to the fact that visible light absorption is minimized in these materials, while they absorb strongly in the UV and NIR wavelengths where the multilayer top electrodes have the highest reflection.

FIG. 19C is a table that summarizes the measured optical and electrical performance (e.g., AVT, SHGC and selectivity values) of transparent OPVs comprising a variety of electrode combinations as discussed in FIGS. 10, 13, 14A-C, and 15A-D, if they were to be integrated into an insulated glass unit as in FIG. 19A, according to some embodiments of the present invention. SHGC and selectivity values for the IGU were calculated from the experimental spectra as described above.

As shown in FIG. 19C, the measured AVT, SHGC, and selectivity values of Stacks #1-#3 closely match the simulated values as shown in FIG. 19B. Through the use of a multilayer top electrode with two Ag layers in Stacks 3 and 10, SHGC can be lowered while maintaining a high AVT of the photovoltaic device, achieving selectivity values as high as 2.0.

Although the disclosure has been described with respect to specific embodiments, it will be appreciated that the disclosure is intended to cover all modifications and equivalents within the scope of the following claims.

A recitation of “a”, “an” or “the” is intended to mean “one or more” unless specifically indicated to the contrary. The use of “or” is intended to mean an “inclusive or,” and not an “exclusive or” unless specifically indicated to the contrary. Reference to a “first” element does not necessarily require that a second element be provided. Moreover reference to a “first” or a “second” element does not limit the referenced element to a particular location unless expressly stated.

Although some embodiments have been discussed in terms of a layer, the term layer should be understood such that a layer can include a number of sub-layers that are built up to form the layer of interest. Thus, the term layer is not intended to denote a single layer consisting of a single material, but to encompass one or more materials layered in a composite manner to form the desired structure. One of ordinary skill in the art would recognize many variations, modifications, and alternatives.

It is also understood that the examples and embodiments described herein are for illustrative purposes only and that various modifications or changes in light thereof will be suggested to persons skilled in the art and are to be included within the spirit and purview of this application and scope of the appended claims.

### LIST OF ABBREVIATIONS

TPBi: 2,2′,2″-(1,3,5-Benzinetriyl)-tris(1-phenyl-1-H-benzimidazole)
HATCN: Dipyrazino[2,3-f:2′,3′-h]quinoxaline-2,3,6,7,10,11-hexacarbonitrile
TAPC: 4,4′-Cyclohexylidenebis[N,N-bis(4-methylphenyl)benzenamine]
BCP: Bathocuproine
BPhen: Bathophenanthroline
Spiro-OMeTAD: N2,N2,N2′,N2′,N7,N7,N7′,N7′-octakis(4-methoxyphenyl)-9,9′-spirobi[9H-fluorene]-2,2′,7,7′-tetramine
NTCDA: 1,4,5,8-Naphthalenetetracarboxylic dianhydride
NTCDI: Napthalenetetracarboxylic diimide
PTCBI: Bisbenzimidazo[2,1-a:1′,2-b′ ]anthra[2,1,9-def:6,5,10-d′e′f]diisoguinoline-10,21-dione
NPB: N,N′-Bis(naphthalen-1-yl)-N,N′-bis(phenyl)-benzidine
NPD: N,N′-Bis(naphthalen-1-yl)-N,N′-bis(phenyl)-2,2′-dimethylbenzidine
TPTPA: Tris(4-(5-phenylthiophen-2-yl)phenyl)amine
PEI: polyethylenimine
PEIE: polyethylenimine ethoxylated
PEDOT:PSS: poly(3,4-ethylenedioxythiophene) polystyrene sulfonate
AZO: Aluminum-doped zinc oxide
IZO: Indium-doped zinc oxide
ITO: Indium-doped tin oxide
IZO: Indium-doped zinc oxide
FTO: fluorine-doped tin oxide

What is claimed is:

1. A transparent photovoltaic device comprising:
a transparent substrate;
a transparent bottom electrode coupled to the transparent substrate;
an active layer coupled to the transparent bottom electrode; and
a transparent multilayer top electrode comprising:
a seed layer coupled to the active layer; and
a metal layer coupled to the seed layer;
wherein the transparent photovoltaic device is characterized by an average visible transmission (AVT) greater than 25% and a top electrode sheet resistance that is less than 100 Ohm/sq.

2. The transparent photovoltaic device of claim 1 wherein:
the seed layer is deposited on the active layer; and
the metal layer is deposited on the seed layer.

3. The transparent photovoltaic device of claim 1 wherein a ratio of the AVT to fraction of transmitted solar radiation (AVT/Tsol) is greater than 1.3 and less than or equal to 2.5 and the emissivity is less than 0.2.

4. The transparent photovoltaic device of claim 1 wherein the seed layer is charge selective.

5. The transparent photovoltaic device of claim 1 wherein the seed layer comprises TPBi:C60, ZnO, or some combination thereof.

6. The transparent photovoltaic device of claim 1 wherein the seed layer has a thickness ranging from 0.1 nm to 100 nm and the metal layer has a thickness ranging from 3 nm to 30 nm.

7. The transparent photovoltaic device of claim 1 wherein the transparent multilayer top electrode further comprises an anti-reflection layer deposited on the metal layer.

8. The transparent photovoltaic device of claim 1 wherein the active layer comprises a tandem cell connected through one or more charge recombination zones.

9. The transparent photovoltaic device of claim 1 wherein the active layer is transparent in the visible wavelength range and exhibits selective absorption in the UV or NIR.

10. The transparent photovoltaic device of claim 1 wherein the transparent bottom electrode comprises:
a first transparent seed layer;
a second metal layer deposited on the seed layer; and
a second transparent charge selective layer deposited on the metal layer.

11. A transparent photovoltaic device comprising:
a transparent substrate;
a transparent bottom electrode coupled to the transparent substrate;
an active layer coupled to the transparent bottom electrode; and
a transparent multilayer top electrode comprising:
a seed layer deposited on the active layer;
a first metal layer deposited on the seed layer;
an interconnect layer deposited on the first metal layer; and
a second metal layer deposited on the interconnect layer. wherein the transparent photovoltaic device is characterized by an average visible transmission (AVT) greater than 25%, and a top electrode sheet resistance that is less than 100 Ohm/sq.

12. The transparent photovoltaic device of claim 11 wherein the interconnect layer comprises a conductive transparent oxide.

13. The transparent photovoltaic device of claim 11 wherein a ratio of the AVT to fraction of transmitted solar radiation (AVT/Tsol) is greater than 1.7 and less than or equal to 2.5 and the emissivity is less than 0.2.

14. The transparent photovoltaic device of claim 11 further comprising an anti-reflection layer deposited on the second metal layer.

15. The transparent photovoltaic device of claim 11 wherein the transparent bottom electrode comprises:
a first transparent seed layer;
a third metal layer deposited on the first transparent seed layer; and
a second transparent charge selective layer deposited on the third metal layer.

16. An insulated glass unit including a transparent photovoltaic device, the insulated glass unit comprising:
a first glazing; and
a second glazing opposing the first glazing;
wherein the transparent photovoltaic device is disposed between the first glazing and the second glazing and comprises:
a transparent substrate;
a transparent bottom electrode coupled to the transparent substrate;
an active layer coupled to the transparent bottom electrode; and
a transparent multilayer top electrode comprising:
a charge selective seed layer coupled to the active layer; and
a metal layer coupled to the charge selective seed layer;
wherein the insulated glass unit is characterized by an average visible transmission (AVT) greater than 25%.

17. The insulated glass unit of claim 16 wherein the insulated glass unit is characterized by a selectivity greater than 1.3 and less than or equal to 2.5.

18. The insulated glass unit of claim 16 wherein the transparent multilayer top electrode further comprises one or more interconnect layers and one or more additional metal layers, each of the one or more interconnect layers being coupled to an adjacent metal layer of the one or more additional metal layers.

19. The insulated glass unit of claim 18 wherein the insulated glass unit is characterized by a selectivity greater than 1.7 and less than or equal to 2.5.

20. The insulated glass unit of claim 16 wherein the transparent photovoltaic device further comprises an anti-reflection layer deposited on the metal layer.
